(19) United States
(12) Patent Application Publication
(10) Pub. No.: US 2026/0150520 A1
(43) Pub. Date: May 28, 2026

(54) DISPLAY PANEL AND DISPLAY APPARATUS

(71) Applicants: Hefei Visionox Technology Co., Ltd., Hefei (CN); Visionox Technology Inc., Kunshan (CN)

(72) Inventors: Zhiwei ZHOU, Hefei (CN); Peng QIN, Kunshan (CN); Jinfang ZHANG, Hefei (CN); Yuting FU, Hefei (CN)

(73) Assignees: Hefei Visionox Technology Co., Ltd., Hefei (CN); Visionox Technology Inc., Kunshan (CN)

(21) Appl. No.: 19/393,504

(22) Filed: Nov. 18, 2025

(30) Foreign Application Priority Data
Nov. 25, 2024 (CN) 202411692854.0

(51) Int. Cl. H10K 59/122; H10K 59/80

(52) U.S. Cl. CPC H10K 59/122; H10K 59/873

(57) ABSTRACT

The present application relates to the field of display technologies, and specifically provides a display panel and a display apparatus. The display panel includes a substrate and an isolation structure. The isolation structure is located on the substrate. The isolation structure includes a plurality of connection portions and partition portions. The partition portion is located on a side of the connection portion facing away from the substrate. The isolation structure is provided with a plurality of isolation openings. The isolation opening is enclosed by the connection portion and the partition portion. A side of the connection portion close to the isolation opening is a first sidewall. An included angle exists between a tangent at a point on the first sidewall and a plane in which the substrate is located.

### CROSS-REFERENCE TO RELATED APPLICATIONS

The present application claims priority to the Chinese Patent Application No. 202411692854.0, titled “DISPLAY PANEL AND DISPLAY APPARATUS”, filed on Nov. 25, 2024, and the entire contents of the aforementioned application are hereby incorporated by reference in its entirety.

### FIELD

The present application relates to the field of display technologies, and in particular to a display panel and a display apparatus.

### BACKGROUND

Organic light-emitting diodes (OLED) and flat-panel display apparatuses based on technologies such as the organic light-emitting diodes (OLED) are widely used in various consumer electronics such as mobile phones, televisions, notebook computers, and desktop computers, and predominate in display apparatuses, due to their advantages such as high image quality, energy efficiency, slim design, and a wide range of applications.

However, the use performance of current OLED display products needs to be improved.

### SUMMARY

The present application provides a display panel and a display apparatus, to improve the use performance of a display panel at least to a specific extent.

To achieve the embodiments adopted in the present application is as follows: In one embodiment, a display panel is provided, including a substrate and an isolation structure layer. The isolation structure layer is located on the substrate. The isolation structure layer includes an isolation structure and a plurality of isolation openings enclosed by the isolation structure. The isolation structure includes a plurality of connection portions and partition portions. The partition portion is located on a side of the connection portion facing away from the substrate.

A side of the connection portion close to the isolation opening is a first sidewall. On a section perpendicular to the substrate, an included angle is formed between a tangent at a point on the first sidewall and a plane in which the substrate is located. The included angle is an acute angle.

In the display panel provided in this embodiment of the present application, the included angle formed between the tangent at the point on the first sidewall of the connection portion close to or pointing to the isolation opening and the plane in which the substrate is located is controlled to be an acute angle, and the first sidewall is overall an inclined slope pointing to the isolation opening, thereby reducing difficulty in climbing the slope at the first sidewall by a film layer at which the connection portion is in contact with the first sidewall, ensuring desirable continuity between corresponding film layers, and reducing a probability of display abnormalities due to poor film layer continuity. This structural improvement helps improve the display effect and reliability of the display panel, and can improve the use performance of the display panel to a specific extent.

In one embodiment, on the section perpendicular to the substrate, the included angle ranges from 10° to 70°.

In one embodiment, a material of the connection portion includes at least one of titanium nitride or molybdenum.

In one embodiment, the display panel further includes a pixel define layer. The pixel define layer is located between the substrate and the isolation structure. The pixel define layer is provided with a pixel opening. The pixel opening is arranged corresponding to and in communication with the isolation opening.

In one embodiment, the display panel further includes a display functional layer. The display functional layer is located on the substrate and includes a plurality of light-emitting devices arranged in the corresponding isolation opening. A part of the light-emitting devices covers the pixel opening, and the light-emitting devices at least partially cover a side surface of the pixel define layer facing away from the substrate.

In one embodiment, each light-emitting device includes a first electrode. The first electrode is in contact with the first sidewall.

In one embodiment, the first electrode includes a first sub-portion and a second sub-portion that are connected. The first sub-portion is in contact with the side surface of the pixel define layer facing away from the substrate. The second sub-portion is in contact with the first sidewall of the isolation structure.

In one embodiment, at least part of the first electrode further includes a third sub-portion. The third sub-portion is in contact with a side surface of the connection portion facing away from the substrate. The second sub-portion is connected to the first sub-portion and the third sub-portion.

In one embodiment, a side of the partition portion close to the isolation opening is a second sidewall. At least part of the third sub-portion covers the side surface of the connection portion facing away from the substrate and is in contact with the second sidewall.

In one embodiment, the light-emitting device further includes a light-emitting functional layer. A second electrode is arranged between the substrate and the pixel define layer. A part of the second electrode is exposed from the pixel opening. The first electrode, the light-emitting functional layer, and the second electrode are stacked on the substrate.

The light-emitting functional layer is located between the first electrode and the second electrode and partially covers the side surface of the pixel define layer facing away from the substrate. The light-emitting functional layer passes through the pixel opening to come into contact with the first electrode.

In one embodiment, one of the first electrode and the second electrode is an anode, and the other is a cathode.

In one embodiment, the display panel further includes an encapsulation layer. The encapsulation layer includes:
a first encapsulation sub-portion located on a side of the isolation structure facing away from the substrate; and
a second encapsulation sub-portion located on a side of the light-emitting device facing away from the substrate and connected to the first encapsulation sub-portion.

The second encapsulation sub-portion covers the light-emitting device and at least part of an outer wall of the isolation structure close to the isolation opening.

In one embodiment, in a direction perpendicular to the substrate, a gap or a partial material of the light-emitting device exists between the first encapsulation sub-portion and the side surface of the isolation structure facing away from the substrate.

In one embodiment, above the side of the isolation structure facing away from the substrate, adjacent first encapsulation sub-portions are spaced apart or overlap with each other.

In one embodiment, the partition portion includes a support portion and a crown that are stacked. The crown is located on a side of the support portion facing away from the connection portion. An orthographic projection of the support portion on the substrate is within an orthographic projection of the crown on the substrate.

In one embodiment, the orthographic projection of the support portion on the substrate is within an orthographic projection of the connection portion on the substrate.

In one embodiment, an orthographic projection of the connection portion on the substrate is within the orthographic projection of the crown on the substrate.

In one embodiment, an orthographic projection of the first sidewall on the substrate is within the orthographic projection of the crown on the substrate.

In one embodiment, a material of the crown includes metallic titanium.

In one embodiment, a material of the support portion includes metallic aluminum.

In one embodiment, on the section perpendicular to the substrate, the crown is in a shape of any one of a trapezoid, a rectangle, or an inverted trapezoid.

In one embodiment, the support portion is in a shape of any one of a trapezoid, a rectangle, or an inverted trapezoid.

In one embodiment, the connection portion is in a shape of a trapezoid.

In one embodiment of the present application further provides a display apparatus, including the display panel described in any one of the above embodiments.

The display apparatus provided in this embodiment of the present application includes the above display panel, and the display apparatus includes at least the beneficial effects of any one or more of the above display panels. For the specific effects, references may be made to the above descriptions, which are not described herein again.

The beneficial effects of the display panel and the display apparatus provided in the present application are as follows: Compared with the related art, in the display panel provided in the present application, a manner in which an end, of the first sidewall of the isolation structure pointing to an end of the isolation opening, close to the substrate inclines toward the isolation opening may be adjusted, and the difficulty in climbing by the first electrode prepared at the first sidewall can be reduced, which improves continuity of the first electrode at the first sidewall, and minimizes a possibility of breaking or falling of the first electrode at the first sidewall, thereby achieving signal transmission of the first electrode, and avoiding a possibility of pixel dark spots due to signal transmission abnormalities. This structure can improve the reliability of the display panel and improve the display effect and the use performance of the display panel.

### BRIEF DESCRIPTION OF THE DRAWINGS

To describe the embodiments of the present application more clearly, the following briefly describes the accompanying drawings required for describing the embodiments or the prior art. Apparently, the accompanying drawings in the following description show merely some embodiments of the present application.

FIG. 1 is a schematic structural plan view of a display panel according to an embodiment of the present application;

FIG. 2 is an enlarged view of a structure of an area A in the display panel shown in FIG. 1;

FIG. 3 is a schematic view of a first sectional structure of the display panel shown in FIG. 2;

FIG. 4 is an enlarged view of a structure of an area B in FIG. 3;

FIG. 5 is a schematic view of a second sectional structure of the display panel shown in FIG. 2;

FIG. 6 is an enlarged view of a structure of an area C in FIG. 5; and

FIG. 7 is a schematic structural plan view of a display apparatus according to an embodiment of the present application.

### REFERENCE NUMERALS IN THE FIGURES

1: substrate; 2: isolation structure; 201: isolation opening; 21: connection portion; 211: first sidewall; 212; first end surface; 213: included angle; 22: partition portion; 2201: second sidewall; 221: support portion; 222: crown; 3: pixel define layer; 301: pixel opening; 4: light-emitting device; 41: first electrode; 411: first sub-portion; 412: second sub-portion; 413: third sub-portion; 42: light-emitting functional layer; 43: second electrode; 5: encapsulation layer; 51: first encapsulation sub-portion; 52: second encapsulation sub-portion;
10: display panel; 100: display apparatus.

### DETAILED DESCRIPTION OF THE EMBODIMENTS

In order to make problems to be resolved in the present application, embodiments, and beneficial effects clearer, the present application is further described in detail below with reference to the accompanying drawings and embodiments. It should be understood that the specific embodiments described herein are merely intended to explain the present application, and are not intended to limit the present application.

It should be noted that when an element is referred to as being “fixed to” or “arranged on” another element, it may be directly or indirectly on the another element. When an element is referred to as being “connected to” another element, it may be directly or indirectly connected to the another element.

In the description of the present application, it should be understood that orientation or position relationships indicated by the terms such as “center”, “longitudinal”, “transverse”, “length”, “width”, “thickness”, “on”, “below”, “front”, “back”, “left”, “right”, “vertical”, “horizontal”, “top”, “bottom”, “inside”, “outside”, “clockwise”, “anticlockwise”, “axial direction”, “radial direction”, and “peripheral direction” are based on orientation or position relationships shown in the drawings, and are merely used to facilitate description of the present application and simplify the description, rather than indicating or implying that an apparatus or an element referred to needs to have a particular orientation or be constructed and operated in a particular orientation. Therefore, such terms cannot be understood as a limitation on the present application.

In addition, the terms “first” and “second” are merely used for description, and cannot be understood as indicating or implying relative importance or implicitly indicating a quantity of indicated features. Therefore, features defined by “first” or “second” may explicitly or implicitly include one or more of the features. In the description of the present application, “a plurality of” means two or more, unless explicitly and specifically defined otherwise.

In the present application, unless otherwise explicitly specified and defined, the terms such as “mount”, “connected”, “connect”, and “fix” should be understood in a broad sense. For example, they may be a fixed connection, a detachable connection, or an integral connection, or may be a mechanical connection, an electrical connection, or mutual communication; or may be a direct connection or an indirect connection through an intermediate medium, or may be communication between interiors of two elements or interaction between two elements. It may understand the specific meanings of the above terms in the present application according to specific circumstances.

In the present application, unless otherwise explicitly specified and defined, a first feature being “on” or “under” a second feature may mean that the first feature is in direct contact with the second feature, or the first feature is in indirect contact with the second feature by using an intermediate medium. In addition, the first feature being “above”, “over”, or “on” the second feature may mean that the first feature is directly or obliquely above the second feature, or merely indicate that the first feature is at a higher horizontal position than the second feature. The first feature being “below”, “under”, and “beneath” the second feature may mean that the first feature is directly or obliquely below the second feature, or merely indicate that the first feature is at a lower horizontal position than the second feature.

In the present application, the term “one embodiment,” “some embodiments,” “example,” “specific example”, “some examples”, or the like means that specific features, structures, materials, or characteristics described in combination with the embodiment or example are included in at least one embodiment or example of the present application. In this specification, the schematic descriptions of the above terms do not necessarily refer to the same embodiment or example. In addition, the described specific features, structures, materials, or characteristics may be combined in a proper manner in any one or more embodiments or examples. In addition, different embodiments or examples and features of the different embodiments or examples described in this specification may be combined or integrated, without conflicting with each other.

The term “layer” used herein may refer to a part of a material that includes an area having a specific thickness. The layer may extend over an entire underlying or overlying structure, or may have a smaller range than the underlying or overlying structure. In addition, the layer may be an area of a continuous structure that is homogeneous or non-homogeneous, and a thickness of the layer is less than a thickness of the continuous structure. For example, the layer may be located between top and bottom surfaces of the continuous structure or between any pair of transverse planes on the top and bottom surfaces. The layer may extend laterally, vertically, and/or along a tapered surface. A substrate may be a layer, may include one or more layers therein, and/or may have one or more layers located on, above, and/or below the substrate. The layer may include a plurality of layers. For example, an interconnection layer may include one or more conductor and contact layers (within which contacts, interconnect lines, and/or vias are formed), and one or more dielectric layers.

During implementation of the present application, the inventors have found that there are the following problems in the related art. Some pixel units have display abnormalities, which affects a display effect of a display panel 10 to a specific extent, affecting the use performance of the display panel and reducing the reliability of the display panel 10.

Based on this, an embodiment of the present application provides a display panel 10, to alleviate or ameliorate the problem at least to a specific extent.

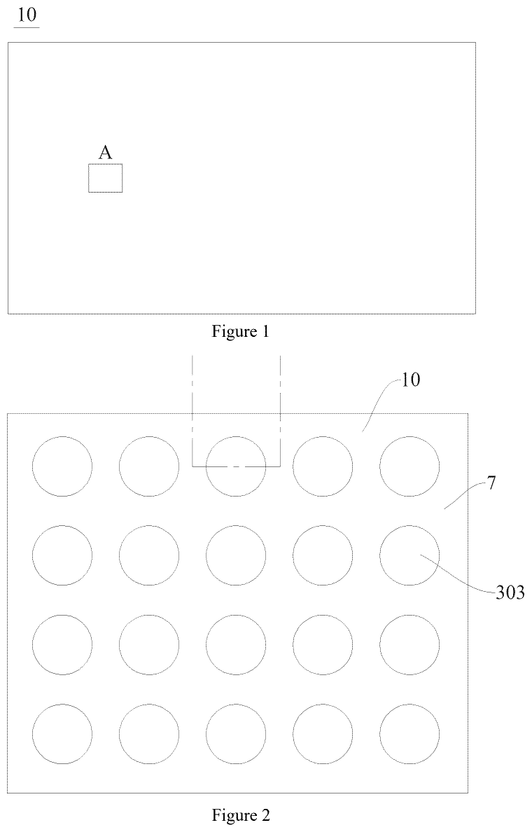

Referring to FIG. 1 and FIG. 2, an embodiment of the present application provides a display panel 10. The display panel 10 includes a substrate 1 and an isolation structure 2. The isolation structure 2 is located on the substrate 1. The isolation structure 2 is provided with an isolation opening 201.

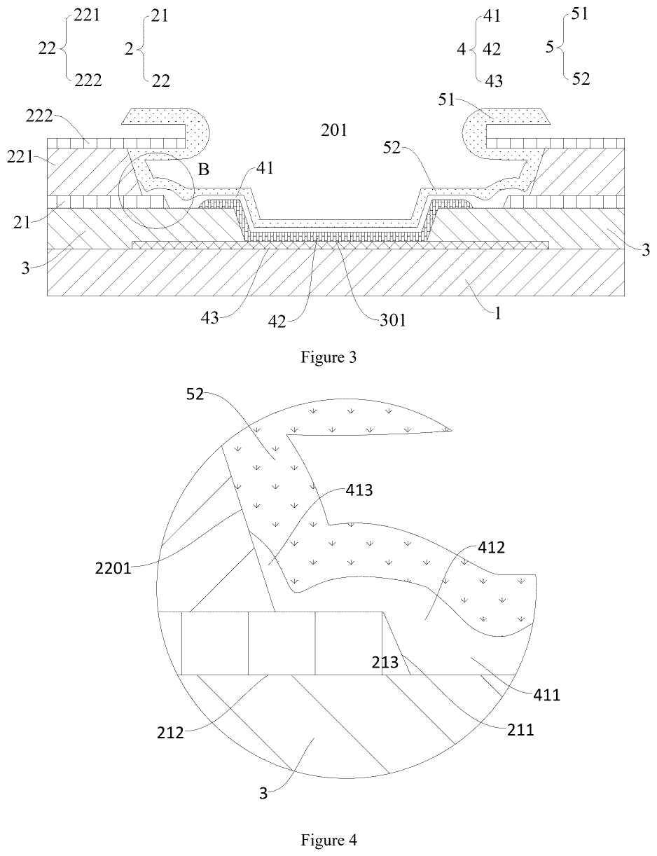

Specifically, referring to FIG. 3, the isolation structure 2 includes a connection portion 21 and a partition portion 22 that are stacked on the substrate 1. The partition portion 22 is located on a side of the connection portion 21 facing away from the substrate 1. The isolation opening 201 is enclosed by the connection portion 21 and the partition portion 22.

Content of the isolation structure 2 mentioned below is further described in patents CN118251982A, 202410864269.8, PCT/CN2024/098407, PCT/CN2024/102783,PCT/CN2024/098217, PCT/CN2024/099419, PCT/CN2024/099072, CN117979755A, CN117998900A, CN117062489A, CN117580403A, CN116583155A, CN116669477A, CN117396039A, CN116669480A, CN116600606A, and CN117500332A for reference.

Referring to FIG. 3, a side of the connection portion 21 close to the isolation opening 201 is provided with an inclination angle. The inclination angle is formed on a side of the connection portion 21 close to the substrate 1 and pointing to the isolation opening 201.

The side of the connection portion 21 close to the isolation opening 201 is defined as a first sidewall 211. On a section perpendicular to the substrate 1, an included angle 213 is formed between a tangent at a point on the first sidewall 211 and a part, of a plane in which the substrate 1 is located, corresponding to the connection portion 21. The included angle 213 is an acute angle.

In this case, the first sidewall 211 is overall a slope inclined toward a side close to the isolation opening 201 and the substrate 1.

The first sidewall 211, through the inclined design, can effectively reduce an amplitude of variation of height differences between the connection portion 21 that supports other subsequent film layers and adjacent film layers. In this way, a thickness of the connection portion 21 gradually increases from an end portion toward a direction away from the isolation opening 201, to make a thickness variation of the connection portion 21 as smooth as possible, and improve an amplitude of variation of thicknesses at different positions of the connection portion 21. This structural design facilitates smooth attachment and overlapping of the subsequent film layers, which prevents discontinuities in the film layers that are overlapped on the connection portion 21, and ensures good continuity of the film layers, thereby resolving problems such as poor signal transmission or signal interruption caused by film layer breaking, and improving the reliability and use performance of the display panel 10.

For example, when an electrode is arranged on a side surface of the connection portion 21 facing away from the substrate 1, the relatively flat first sidewall 211 allows the electrode to be smoothly overlapped along the surface, which helps improve the continuity of the electrode.

In some embodiments, the surface of the first sidewall 211 is a smooth surface, or may be a surface with low roughness.

It should be noted that, in other embodiments, the first sidewall 211 may not be an inclined surface or a smooth curved surface, and the first sidewall 211 is overall a slope inclined downward.

In the display panel 10 provided in this embodiment of the present application, the included angle formed between the tangent at the point on the first sidewall 211 of the connection portion 21 close to or pointing to the isolation opening 201 and the plane in which the substrate 1 is located is controlled to be an acute angle, and the first sidewall 211 is overall an inclined slope pointing to the isolation opening 201, thereby reducing difficulty in climbing the slope at the first sidewall by a film layer at which the connection portion 21 is in contact with the first sidewall 211, ensuring desirable continuity between corresponding film layers, and reducing a probability of display abnormalities due to poor film layer continuity. This structural improvement helps improve the display effect and reliability of the display panel 10, and can improve the use performance of the display panel 10 to a specific extent.

In some embodiments, a side of the connection portion 21 close to the substrate 1 has a first end surface 212, and an end of the first sidewall 211 close to the isolation opening 201 can intersect with the first end surface 212. The first sidewall 211 and the first end surface 212 can intersect to form the included angle 213, provided that a part of the first end surface 212 for intersecting with the first sidewall 211 is parallel to the plane in which the substrate 1 is located. In other words, the included angle 213 may be formed at the intersection of the first sidewall 211 and the first end surface 212.

Referring to FIG. 4, on the section perpendicular to the substrate 1, the included angle 213 is an acute angle.

Specifically, the included angle 213 does not exceed 70°; and/or the included angle 213 is not less than 10°.

Specifically, the included angle 213 may be set to a value ranging from 10° to 70°. The specific value range of the included angle may be adjusted according to an actual requirement. For example, the angle may be any one of 10°, 15°, 20°, 25°, 30°, 35°, 40°, 45°, 50°, 55°, 60°, 65°, 70°, etc.

When the included angle 213 is excessively large, the first sidewall 211 formed by the connection portion 21 is relatively steep, which may result in difficulty in subsequently climbing the slope by a film layer at which the connection portion 21 is in contact with the first sidewall 211, and is likely to lead to difficulty in overlapping corresponding film layers, resulting in film layer breaking and affecting normal signal transmission. When the included angle 213 is excessively small, the connection portion 21 extends by an excessively long distance toward the isolation opening 201 relative to the partition portion 22, which may result in a risk of causing a film layer not contacting the connection portion 21 in the design to contact the connection portion 21, affecting the normal display function of the display panel 10.

It should also be noted that a part of the first sidewall 211 that is in contact with the first end surface 212 cannot be located on a side away from the isolation opening 201 relative to the first sidewall 211. Otherwise, a peripheral side edge of the connection portion 21 forms an inverted taper angle structure, which further increases difficulty in overlapping subsequent film layers on the first sidewall 211, or even leads to direct breaking of a cathode at the first sidewall.

In some embodiments, the first sidewall 211 in the connection portion 21 may be formed through dry etching. Due to the directional property of dry etching, it can be ensured that the prepared connection portion 21 is etched relatively accurately, to achieve a clear and regular edge of the first sidewall 211, which satisfies a design requirement on a shape of the first sidewall 211.

In some embodiments, a material of the connection portion 21 includes at least one of titanium nitride or molybdenum. Taking titanium nitride as an example, the connection portion 21 prepared from titanium nitride has a specific thickness and may be prepared through dry etching to obtain the inclined first sidewall 211, thereby satisfying a requirement on electrical performance of related components in display panels.

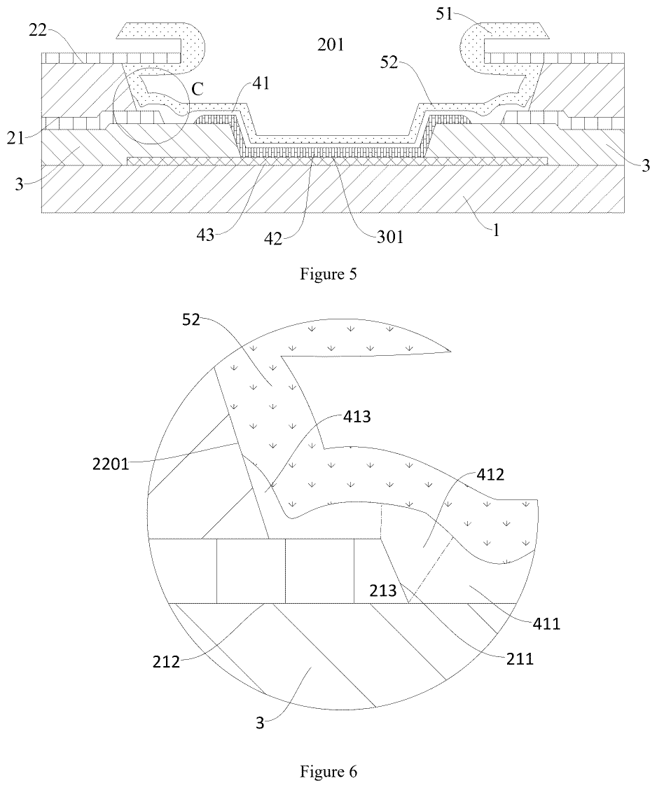

In some embodiments, referring to FIG. 3 and FIG. 5, the display panel 10 further includes a pixel define layer 3, and the pixel define layer 3 is located between the substrate 1 and the isolation structure 2.

The pixel define layer 3 is provided with a pixel opening 301, and the pixel opening 301 is arranged corresponding to and in communication with the isolation opening 201.

The pixel define layer 3 is an inorganic layer that may be configured to define a pixel range, to ensure that all pixels are independent of each other, and block moisture in the substrate 1, to prevent external factors such as water and oxygen from eroding a relevant film layer located on a side of the pixel define layer 3 facing away from the substrate 1.

The first end surface 212 of the connection portion 21 is attached to a side surface of the pixel define layer 3 facing away from the substrate 1. The first sidewall 211 and the first end surface 212 intersect exactly on the side surface of the pixel define layer 3 facing away from the substrate 1.

In the direction perpendicular to the plane in which the substrate 1 is located, initial thicknesses at all positions of the pixel define layer 3 are substantially the same.

The isolation structure 2 configured to enclose the isolation opening 201 is described in detail below.

In the direction perpendicular to the plane in which the substrate 1 is located, a sectional shape of the isolation structure 2 resembles a rectangular or trapezoidal structure, or the sectional shape of the isolation structure 2 may be in a shape that is wider at the top and narrower at the bottom. An orthographic projection of an end of the isolation structure 2 close to the substrate 1 on the substrate 1 is within an orthographic projection of an end of the isolation structure 2 facing away from the substrate 1 on the substrate 1.

The isolation structure 2 includes a connection portion 21 and a partition portion 22. The partition portion 22 may be a single-layer structure or a multi-layer structure. When the partition portion 22 is a multi-layer structure, in some embodiments, the partition portion 22 includes a support portion 221 and a crown 222 that are stacked. The crown 222 is located on a side of the support portion 221 facing away from the connection portion 21.

Referring to FIG. 3, an orthographic projection of the support portion 221 on the substrate 1 is within an orthographic projection of the crown 222 on the substrate 1.

It may be determined through further comparison of a dimension relationship among the connection portion 21, the support portion 221, and the crown 222 that the orthographic projection of the support portion 221 on the substrate 1 is within an orthographic projection of the connection portion 21 on the substrate 1, the orthographic projection of the connection portion 21 on the substrate 1 is within the orthographic projection of the crown 222 on the substrate 1, and an orthographic projection of the first sidewall 211 on the substrate 1 is within the orthographic projection of the crown 222 on the substrate 1.

In some embodiments, a sidewall on a side of the support portion 221 facing the isolation opening 201 is offset toward a side away from the isolation opening 201 relative to the first sidewall 211 of the connection portion 21, and a sectional sidewall of the isolation structure 2 is in a shape similar to an eave.

Certainly, in other same or similar embodiments, the dimension and projection relationships among the connection portion 21, the support portion 221, and the crown 222 may be adaptively adjusted according to a design requirement.

In some embodiments, the support portion 221 has a larger thickness than the crown 222, and the crown 222 has a substantially same thickness as the connection portion 21, or the crown 222 has a larger thickness than the connection portion 21.

In some embodiments, on the section perpendicular to the substrate 1, the support portion 221 is in a shape of any one of a trapezoid, a rectangle, or an inverted trapezoid. Referring to FIG. 3, the support portion 221 in the figure is a trapezoidal structure.

In some embodiments, on the section perpendicular to the substrate 1, the crown 222 is in a shape of any one of a trapezoid, a rectangle, or an inverted trapezoid. The connection portion 21 is a trapezoidal structure.

In some embodiments, the connection portion 21, the support portion 221, and the crown 222 may be an integrally formed structure, or may be obtained by sequentially stacking different materials.

Specifically, a material of the crown 222 includes metallic titanium, which is a titanium metal layer. A material of the support portion 221 includes metallic aluminum, which is an aluminum metal layer. A material of the connection portion 21 includes at least one of titanium nitride or molybdenum described above.

In some embodiments, a second electrode 43 is further arranged between the pixel define layer 3 and the substrate 1. A part of the second electrode 43 is exposed from the pixel opening 301 relative to the isolation opening 201, and a part of the second electrode 43 is covered by the pixel define layer 3.

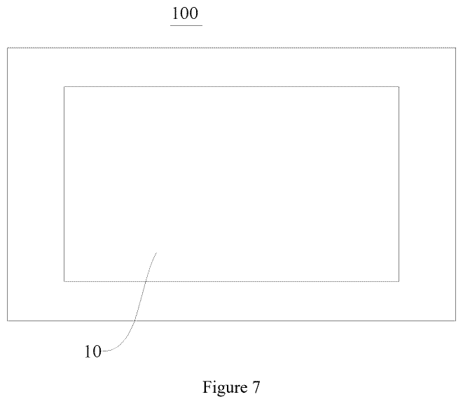

Referring to FIG. 3 and FIG. 4, a projection of the connection portion 21 in a thickness direction of the substrate 1 and a projection of the second electrode 43 in the thickness direction of the substrate 1 do not coincide, a side surface of the connection portion 21 that is in contact with the pixel define layer 3 is a relatively flat surface, and the surface is the first end surface 212. Referring to FIG. 5 and FIG. 6, when the projection of the connection portion 21 in the thickness direction of the substrate 1 and the projection of the second electrode 43 in the thickness direction of the substrate 1 coincide, under the influence of the second electrode 43, although the pixel define layer 3 located on a side of the connection portion 21 close to the substrate 1 may have a substantially consistent thickness at different positions, a height of the side surface of the pixel define layer 3 facing away from the substrate 1 varies at different positions. This results in an uneven surface on a side of the connection portion 21 that is in contact with the pixel define layer 3. In this case, the first end surface 212 is formed on a peripheral side of a side of the connection portion 21 close to the pixel define layer 3. In FIG. 5 and FIG. 6, a middle part on an end of the connection portion 21 close to the pixel define layer 3 is located on an end of the first end surface 212 close to the substrate 1, and

the first end surface 212 intersects with the first sidewall 211. Therefore, the first end surface 212 is certainly located on the side of the connection portion 21 close to or pointing to the isolation opening 201.

Referring to FIG. 4 and FIG. 6, the display panel 10 further includes a display functional layer.

The display functional layer is located on the substrate 1, and includes a plurality of light-emitting devices 4 located in the corresponding isolation opening 201. A part of the light-emitting devices 4 covers the pixel opening 301, and the light-emitting devices at least partially cover the side surface of the pixel define layer 3 facing away from the substrate 1.

The light-emitting device 4 includes the second electrode 43 described above, and further includes a first electrode 41 stacked together with the second electrode 43. The first electrode 41 is in contact with the first sidewall 211 of the connection portion 21.

Referring to FIG. 4, the first electrode 41 is located on the side of the pixel define layer 3 facing away from the substrate 1, and covers a part of a surface on the side of the pixel define layer 3 facing away from the substrate 1, and the first electrode 41 can be connected to the connection portion 21.

An orthographic projection of the first electrode 41 on the substrate 1 and the orthographic projection of the connection portion 21 on the substrate 1 partially coincide.

Specifically, the first electrode 41 includes a first sub-portion 411 and a second sub-portion 412 that are connected. The first sub-portion 411 is configured to be in contact with the side surface of the pixel define layer 3 facing away from the substrate 1, and the second sub-portion 412 is configured to be in contact with the first sidewall 211 of the isolation structure 2.

Due to machining errors, there is a possibility that the second sub-portion 412 is not in contact with the first sidewall 211 of the isolation structure 2. To further improve the reliability of the display panel 10, in some embodiments, at least part of the first electrode 41 further includes a third sub-portion 413.

The third sub-portion 413 is in contact with at least part of a surface on the side of the connection portion 21 facing away from the substrate 1, and the third sub-portion 413 is connected to the second sub-portion 412.

Under the action of the second sub-portion 412, the first sub-portion 411 and the third sub-portion 413 are connected and form a continuous first electrode 41. The inclined surface of the first sidewall 211 of the connection portion 21 helps improve the continuity of the first electrode 41, and the first electrode 41 can easily achieve reliable electrical connection to the connection portion 21.

A side, of the partition portion 22 located on the side of the connection portion 21 facing away from the substrate 1, close to the isolation opening 201 has a second sidewall 2201, and at least part of the third sub-portion 413 can cover at least part of the second sidewall 2201.

Referring to FIG. 4 and FIG. 6, the third sub-portion 413 covers a part of a surface on a side of the second sidewall 2201 close to the connection portion 21.

The second sidewall 2201 may be perpendicular to the substrate 1, or may be arranged obliquely relative to the substrate 1. In some embodiments, the second sidewall 2201 is an inclined surface, and an inclination direction of the second sidewall 2201 is substantially the same as the inclination direction of the first sidewall 211.

The light-emitting device 4 further includes a light-emitting functional layer 42. The light-emitting functional layer 42 is located between the first electrode 41 and the second electrode 43. A side of the light-emitting functional layer 42 close to the substrate 1 is connected to the second electrode 43, and a side of the light-emitting functional layer 42 facing away from the substrate 1 is connected to the first electrode 41.

Referring to FIG. 3, the first electrode 41 covers a side surface of the light-emitting functional layer 42 facing away from the substrate 1, and extends along the surface of the light-emitting functional layer 42 to contact the pixel define layer 3 and the connection portion 21.

Referring to FIG. 4, the light-emitting functional layer 42 may pass through the pixel opening 301 to come into contact with the first electrode 41, and an orthographic projection of the pixel opening 301 on the substrate 1 is within an orthographic projection of the light-emitting functional layer 42 on the substrate 1.

The first electrode 41 covers the light-emitting functional layer 42 through the first sub-portion 411. In addition, the light-emitting functional layer 42 may pass through the pixel opening 301 to come into contact with a surface of the second electrode 43 located between the pixel define layer 3 and the substrate 1.

It should be noted that an orthographic projection of the light-emitting functional layer 42 on the substrate 1 is spaced apart from the orthographic projection of the connection portion 21 on the substrate 1, that is, the light-emitting functional layer 42 is in a non-contact state with the connection portion 21.

The isolation structure 2 may achieve isolation between the light-emitting functional layers 42 located in different isolation openings 201 and the first electrode 41 by using the isolation openings 201, and the light-emitting functional layers 42 located in the different isolation openings 201 and the first electrode 41 can remain independent of and unconnected to each other.

Specifically, the light-emitting functional layer 42 may be made from a small-molecule organic light emitting material, a complex light emitting material, a high-molecular polymer, and the like. Different light-emitting functional layers 42 can emit light of different colors. Generally, three types of light-emitting functional layers 42 are arranged, which are respectively configured to emit red, green, and blue light.

One or more of the three different light-emitting functional layers 42 may be respectively arranged in the different isolation openings 201 according to a design requirement.

One of the first electrode 41 and the second electrode 43 is an anode, and the other is a cathode. In some embodiments, the first electrode 41 is an anode, and the second electrode 43 is a cathode. Certainly, as needed, the first electrode 41 may be adjusted to be a cathode, and the second electrode 43 may be adjusted to be an anode.

Referring to FIG. 3 to FIG. 6, the display panel 10 further includes an encapsulation layer 5.

Specifically, at least part of the encapsulation layer 5 is located in the isolation opening 201 and covers the light-emitting device 4 and a sidewall on the side of the isolation structure 2 close to the isolation opening 201.

Specifically, the encapsulation layer 5 includes a plurality of encapsulation units spaced apart, and the plurality of encapsulation units are arranged in a one-to-one correspondence with the isolation openings 201.

Each encapsulation unit includes a first encapsulation sub-portion 51 and a second encapsulation sub-portion 52 that are connected. The first encapsulation sub-portion 51 is located on a side of the isolation structure 2 facing away from the substrate 1, and the second encapsulation sub-portion 52 is located on a side of the light-emitting device 4 facing away from the substrate 1, and is connected to the first encapsulation sub-portion 51.

Referring to FIG. 4 and FIG. 6, a middle part of the second encapsulation sub-portion 52 covers the light-emitting device 4, and the other part is configured to cover at least part of an outer wall of the isolation structure 2 close to the isolation opening 201 and may extend toward a side facing away from the substrate 1 to connect to the first encapsulation sub-portion 51.

It should be noted that, in the direction perpendicular to the substrate 1, a gap or a partial material of the light-emitting device exists between the first encapsulation sub-portion 51 and a side surface of the isolation structure 2 facing away from the substrate 1, which relates to the dry etching process or the wet etching process that are used. In this case, the first encapsulation sub-portion 51 is floated relative to the side surface of the isolation structure 2 facing away from the substrate 1, and the second encapsulation sub-portion 52 extends along an end of the crown 222 of the isolation structure 2 pointing to the isolation opening 201 and is connected to the first encapsulation sub-portion 51.

In some embodiments, above the side of the isolation structure 2 facing away from the substrate 1, adjacent first encapsulation sub-portions 51 exist. The adjacent first encapsulation sub-portions 51 are spaced apart, or the adjacent first encapsulation sub-portions 51 overlap with each other above the isolation structure 2.

In each isolation opening 201, the encapsulation unit formed by the first encapsulation sub-portion 51 and the second encapsulation sub-portion 52 is a continuous film layer structure, and the encapsulation unit provides a desirable encapsulation effect for the corresponding isolation opening 201 and the light-emitting device 4 located therein.

A second encapsulation layer and a third encapsulation layer are further arranged on the first encapsulation layer. The second encapsulation layer is an organic material layer, and the third encapsulation layer is an inorganic material layer. A material of the first encapsulation layer may be the same as a material of the third encapsulation layer.

After the isolation opening 201 is encapsulated using the encapsulation layer 5, another film layer structure needs to be further arranged on a side of the encapsulation layer 5 facing away from the substrate 1 for further planarization, encapsulation, and the like of the display panel 10.

Specifically, the side of the encapsulation layer 5 facing away from the substrate 1 is further provided with at least one layer of film layer structure among a planarization layer, an organic encapsulation film layer, an inorganic encapsulation film layer, a touch layer, an organic adhesive layer, and a cover plate.

Taking the planarization layer as an example, a material of the planarization layer may include at least one of an organic material or an inorganic material, for example, an organic polymer (such as polyimide or acrylic resin) or an inorganic material (such as silicon oxide or silicon nitride).

The planarization layer made of the organic material may be prepared using a technology such as an ink-jet printing (IJP) technology. A part of the planarization layer may flow into the isolation opening 201, which fills the isolation opening 201 to improve flatness of the display panel 10, while providing specific protection to the relevant film layers located below the planarization layer. Another part of the planarization layer may cover the above first encapsulation sub-portion 51 and fill a gap formed between the first encapsulation sub-portion 51 and the isolation structure 2. A side surface of the finally prepared planarization layer facing away from the substrate 1 is a flat surface.

It may be understood that, in the display panel 10 provided in this embodiment of the present application, the titanium nitride material that can form a high-precision sidewall is utilized to prepare the connection portion 21 of the isolation structure 2, and the first sidewall 211 of the connection portion 21 is adjusted to an inclined sidewall having a specific angle, and the first sidewall 211 achieves a desirable appearance. This significantly reduces preparation difficulty of the first electrode 41 connected to the connection portion 21 through the first sidewall 211, enables the first electrode 41 to smoothly climb the slope along the first sidewall 211 and form a continuous film layer, and enable the first electrode 41 to achieve smooth transmission of relevant electrical signals. This solution can alleviate the electrode discontinuity problem caused by the appearance of the connection portion 21, achieve effective transmission of electrode signals, can improve the reliability of the display panel 10, and improve the display effect and the use performance of the display panel 10.

In one embodiment of the present application further provides a preparation method for the display panel 10.

The method includes the following steps:

Step S1: Prepare a connection structure layer on a side of a substrate 1, and prepare a partition structure layer on a side of the connection structure layer facing away from the substrate 1.

Step S2: Pattern the partition structure layer to obtain a partition portion 22, and pattern the connection structure layer to obtain a connection portion 21, where the connection portion 21 and the partition portion 22 form an isolation structure 2 provided with an isolation opening 201, and the connection portion 21 and the partition portion 22 enclose the isolation opening 201. A side of the connection portion 21 close to the isolation opening 201 is a first sidewall 211, and an included angle 213 exists between a tangent at a point on the first sidewall 211 and a plane in which the substrate 1 is located. The included angle 213 is an acute angle.

In the preparation method, after the isolation opening 201 is prepared on the isolation structure 2, the first sidewall 211 on the side of the connection portion 21 facing the isolation opening 201 is an inclined slope structure, which improves an appearance at the first sidewall 211, to improve continuity, at the first sidewall 211, of other subsequent film layers for contact with the first sidewall 211, thereby improving signal transmission and improving the reliability and the display effect of the display panel 10.

In some embodiments, a side of the connection portion 21 close to the substrate 1 has a first end surface 212, and an end of the first sidewall 211 close to the isolation opening 201 can intersect with the first end surface 212. The first sidewall 211 and the first end surface 212 can intersect to form the included angle 213, provided that a part of the first end surface 212 for intersecting with the first sidewall 211 is parallel to the plane in which the substrate 1 is located. In other words, the included angle 213 may be formed at the intersection of the first sidewall 211 and the first end surface 212 and pointing to the isolation opening 201.

The structure of the display panel 10 described above can be prepared using the preparation method. For the specific structure, references may be made to the structure in any one of the above embodiments of the display panel 10, which is not described herein again.

Patterning the partition structure layer to obtain the partition portion in step S2 includes the following step:

Step S201: Perform dry etching and/or wet etching on the partition structure layer to obtain the partition portion 22.

The patterning may be understood as a photolithographic patterning process. For example, a photoresist is applied to a structural layer to be patterned, the photoresist is exposed using a mask, the exposed photoresist is developed to obtain a photoresist pattern, and the structural layer is etched (through wet drying or dry etching based on a demand) using the photoresist pattern, to selectively remove the photoresist pattern. It should be noted that, when a material of a corresponding structural layer (for example, the photoresist pattern) includes the photoresist, the structural layer may be directly exposed using the mask, to form a desired pattern.

During the patterning of the partition structure layer, a photoresist may be applied to a side surface of the partition structure layer facing away from the substrate 1, and the partition structure layer may be etched through dry etching and/or wet etching depending on a material of the partition structure layer and a structural requirement, to obtain the partition portion 22.

Specifically, preparing the partition structure layer on the side of the connection structure layer facing away from the substrate 1 in step S1 includes:

preparing a support structure layer on the side of the connection structure layer facing away from the substrate 1, and forming a crown structure layer on a side of the support structure layer facing away from the substrate 1, where the support structure layer and the crown structure layer form the partition structure layer.

During preparation of the partition portion 22 by processing the partition structure layer, since the partition structure layer includes the crown structure layer and the support structure layer that are sequentially stacked, the crown structure layer and the support structure layer need to be etched in sequence, to prepare the partition portion 22.

In some embodiments, a material of the support structure layer includes aluminum. Aluminum metal is deposited on the side of the connection structure layer facing away from the substrate 1 as the support structure layer.

In some embodiments, a material of the crown structure layer includes titanium. Titanium metal is deposited on a side of the support structure layer facing away from the substrate 1 as the crown structure layer.

Specifically, performing dry etching and/or wet etching on the partition structure layer to obtain the partition portion 22 in step S201 includes the following steps:

Step S2011: Perform dry etching on the crown structure layer to obtain a crown 222.

Step S2012: Perform wet etching on the support structure layer to obtain the support portion 221.

Specifically, in step S2011, dry etching may be performed on the crown structure layer by using the photolithographic patterning process, or dry etching may be performed on the crown structure layer by using other processes, to finally obtain the crown 222. In step S2012, wet etching may be performed on the support structure layer by using the photolithographic patterning process, or wet etching may be performed on the support structure layer by using other processes, to finally obtain the support portion 221.

Patterning the connection structure layer to obtain the connection portion 21 in step S2 includes the following step:

Step S202: Perform dry etching on the connection structure layer to obtain the connection portion 21.

For the dry etching process, refer to the above text. Due to the directional property of dry etching, relatively accurate etching can be performed on the connection structure layer, and the first sidewall 211 of the prepared connection layer has a clear and regular edge. The shape of the first sidewall 211 of the connection portion 21 prepared through dry etching satisfies the design requirement, which may be specifically achieved through adjustment of a magnitude of gas concentration, a magnitude of dry etching energy, or the like during the dry etching. In addition, a combination of isotropic dry etching and anisotropic dry etching may be used for etching.

After the etching of the partition structure layer is completed to obtain the partition portion 22 and the etching of the connection structure layer is completed to obtain the connection portion 21 in step S2, a through isolation opening 201 is formed in the isolation structure 2 formed by the partition portion 22 and the connection portion 21. The isolation opening 201 is enclosed by the connection portion and the partition portion 22.

Specifically, the included angle 213 between the tangent at the point on the first sidewall 211 and the plane in which the substrate 1 is located ranges from 10° to 70°.

When the included angle 213 is excessively large, the first sidewall 211 formed by the connection portion 21 is relatively steep, which may result in difficulty in subsequently climbing the slope by a film layer at which the connection portion 21 is in contact with the first sidewall 211, and is likely to lead to difficulty in overlapping corresponding film layers, resulting in film layer breaking and affecting normal signal transmission. When the included angle 213 is excessively small, the connection portion 21 extends by an excessively long distance toward the isolation opening 201 relative to the partition portion 22, which may result in a risk of causing a film layer not contacting the connection portion 21 in the design to contact the connection portion 21, affecting the normal display function of the display panel 10.

It should also be noted that a part of the first sidewall 211 that is in contact with the first end surface 212 cannot be located on a side away from the isolation opening 201 relative to the first sidewall 211. Otherwise, a peripheral side edge of the connection portion 21 forms an inverted taper angle structure, which further increases difficulty in overlapping subsequent film layers on the first sidewall 211, or even leads to direct breaking of a cathode at the first sidewall.

Preparing the connection structure layer on the side of the substrate 1 in step S1 includes:

depositing at least one of titanium nitride or molybdenum on the side of the substrate 1 as the connection structure layer.

The connection structure layer prepared using the material has a specific thickness and may be etched through dry etching, which helps form a connection portion 21 with a desirable appearance. The first sidewall 211 of the connection portion 21 may be an inclined sidewall and have an inclination angle that can be easily controlled.

In this embodiment of the present application, before step S1, the method further includes: preparing a second electrode 43 and a pixel define layer 3 on a side of the substrate 1.

A metal layer may be deposited on a side surface of the substrate 1, and is photolithographically etched to prepare the second electrode 43. A pixel define layer 3 is prepared on a side surface of the second electrode 43 facing away from the substrate 1. The pixel define layer 3 covers the second electrode 43.

After step S2, the present application further includes the following step:

Step S3: Provide a pixel opening 301 on the pixel define layer 3, where the pixel opening 301 is arranged corresponding to and in communication with the isolation opening 201.

A corresponding position of the pixel define layer 3 may be etched through dry etching or the like, to obtain the pixel opening 301. A part of a surface of the second electrode 43 may be exposed from the pixel opening 301. The prepared pixel opening 301 is provided corresponding to and remains in communication with the isolation opening 201 prepared in step S2.

This embodiment of the present application further includes the following steps:

Step S4: Prepare a light-emitting functional layer 42 and a first electrode 41 in the isolation opening 201.

Step S5: Form, on a side of the first electrode 41 facing away from the substrate 1, an encapsulation layer 5 that can cover at least part of a side of the isolation structure 2 facing away from the substrate 1.

The first electrode 41 may climb along the first sidewall 211 relative to the connection portion 21 and cover a side surface of the connection portion 21 facing away from the substrate 1, to improve film layer continuity of the first electrode 41 on the connection portion 21, and the first electrode 41 can achieve signal transmission during use.

It may be understood that, in the preparation method for the display panel 10 provided in this embodiment of the present application, the appearance of the first sidewall 211 of the connection portion 21 on the isolation structure 2 to be climbed and connected by the first electrode 41 may be controlled, and an inclination angle of the first sidewall 211 may be adjusted to be within 10° to 70°, which can effectively resolve a discontinuity problem of the first electrode 41 due to a poor appearance of the first sidewall 211, to achieve signal transmission of the first electrode 41 and reduce a possibility of pixel dark spots due to signal transmission abnormalities. This preparation method can improve the reliability of the display panel 10 and improve the display effect and the use performance of the display panel 10.

In one embodiment, referring to FIG. 7, the present application further provides a display apparatus 100. The display apparatus 100 includes the display panel 10 in any one of the above embodiments.

The display apparatus 100 provided in this embodiment of the present application may be a product or a component with a display function, such as a mobile phone, a notebook computer, a tablet computer, a smart watch, a smart band, a navigator, a display, or a personal digital assistant (PDA).

Since the display panel 10 in the display apparatus 100 has the beneficial effects of any one or more of the above display panels 10, the display apparatus 100 includes at least the beneficial effects of any one or more of the above display panels 10. For the specific effects, references may be to the above descriptions, which are not described herein again.

The above descriptions are merely some embodiments of the present application, and are not intended to limit the present application. Any modification, equivalent replacement, or improvement made without departing from the spirit and principle of the present application shall fall within the protection scope of the present application.

1. A display panel, comprising:
a substrate; and
an isolation structure layer located on the substrate, wherein the isolation structure layer comprises an isolation structure and a plurality of isolation openings enclosed by the isolation structure, the isolation structure comprises a plurality of connection portions and partition portions, and the partition portion is located on a side of the connection portion facing away from the substrate, wherein
a side of the connection portion close to the isolation opening is a first sidewall, and on a section perpendicular to the substrate, an included angle is formed between a tangent at a point on the first sidewall and a plane in which the substrate is located, wherein the included angle is an acute angle.

2. The display panel according to claim 1, wherein the included angle ranges from 10° to 70°.

3. The display panel according to claim 1, wherein a material of the connection portion comprises titanium nitride or molybdenum.

4. The display panel according to any one of claims 1, wherein the display panel further comprises a pixel define layer, the pixel define layer is located between the substrate and the isolation structure, the pixel define layer is provided with a plurality of pixel openings, and the pixel opening is arranged corresponding to and in communication with the isolation opening.

5. The display panel according to claim 4, wherein the display panel further comprises a display functional layer, the display functional layer is located on the substrate and comprises a plurality of light-emitting devices arranged in a one-to-one correspondence with the isolation opening, a part of the light-emitting devices cover the pixel opening, and the light-emitting devices at least partially cover a side surface of the pixel define layer facing away from the substrate.

6. The display panel according to claim 5, wherein each light-emitting device comprises a first electrode, and the first electrode is in contact with the first sidewall.

7. The display panel according to claim 6, wherein the first electrode comprises a first sub-portion and a second sub-portion that are connected, the first sub-portion is in contact with the side surface of the pixel define layer facing away from the substrate, and the second sub-portion is in contact with the first sidewall of the isolation structure.

8. The display panel according to claim 7, wherein at least part of the first electrode further comprises a third sub-portion, the third sub-portion is in contact with a side surface of the connection portion facing away from the substrate, and the second sub-portion is connected to the first sub-portion and the third sub-portion.

9. The display panel according to claim 8, wherein a side of the partition portion close to the isolation opening is a second sidewall, and at least part of the third sub-portion covers the side surface of the connection portion facing away from the substrate and is in contact with the second sidewall.

10. The display panel according to claim 6, wherein the light-emitting device further comprises a light-emitting functional layer;
a second electrode is arranged between the substrate and the pixel define layer, a part of the second electrode is exposed from the pixel opening, and the first electrode, the light-emitting functional layer, and the second electrode are stacked on the substrate; and
the light-emitting functional layer is located between the first electrode and the second electrode and partially covers the side surface of the pixel define layer facing away from the substrate, and the light-emitting functional layer passes through the pixel opening to come into contact with the first electrode.

11. The display panel according to claim 10, wherein one of the first electrode and the second electrode is an anode, and the other is a cathode.

12. The display panel according to claim 5, wherein the display panel further comprises a first encapsulation layer, the first encapsulation layer comprises a plurality of encapsulation layers arranged corresponding to the light-emitting devices, and each of the encapsulation layers comprises:
a first encapsulation sub-portion located on a side of the isolation structure facing away from the substrate; and
a second encapsulation sub-portion located on a side of the light-emitting device facing away from the substrate and connected to the first encapsulation sub-portion, wherein
the second encapsulation sub-portion covers the light-emitting device and at least part of an outer wall of the isolation structure close to the isolation opening.

13. The display panel according to claim 12, wherein in a direction perpendicular to the substrate, a gap or a partial material of the light-emitting device exists between the first encapsulation sub-portion and the side surface of the isolation structure facing away from the substrate.

14. The display panel according to claim 13, wherein above the side of the isolation structure facing away from the substrate, adjacent first encapsulation sub-portions are spaced apart or overlap with each other.

15. The display panel according to claim 1, wherein the partition portion comprises a support portion and a crown that are stacked, the crown is located on a side of the support portion facing away from the connection portion, and an orthographic projection of the support portion on the substrate is within an orthographic projection of the crown on the substrate.

16. The display panel according to claim 15, wherein the orthographic projection of the support portion on the substrate is within an orthographic projection of the connection portion on the substrate.

17. The display panel according to claim 15, wherein an orthographic projection of the connection portion on the substrate is within the orthographic projection of the crown on the substrate; and an orthographic projection of the first sidewall on the substrate is within the orthographic projection of the crown on the substrate.

18. The display panel according to claim 15, wherein a material of the crown comprises metallic titanium.

19. The display panel according to claim 15, wherein on the section perpendicular to the substrate, the crown is in a shape of any one of a trapezoid, a rectangle, or an inverted trapezoid.

20. A display apparatus, comprising a display panel, the display panel, comprising:
a substrate; and
an isolation structure layer located on the substrate, wherein the isolation structure layer comprises an isolation structure and a plurality of isolation openings enclosed by the isolation structure, the isolation structure comprises a plurality of connection portions and partition portions, and the partition portion is located on a side of the connection portion facing away from the substrate, wherein
a side of the connection portion close to the isolation opening is a first sidewall, and on a section perpendicular to the substrate, an included angle is formed between a tangent at a point on the first sidewall and a plane in which the substrate is located, wherein the included angle is an acute angle.
